(19) United States
(12) Patent Application Publication
(10) Pub. No.: US 2021/0109140 A1
(43) Pub. Date: Apr. 15, 2021

(54) METHOD FOR IDENTIFYING PARAMETERS OF 10 KV STATIC LOAD MODEL BASED ON SIMILAR DAILY LOAD CURVES

(71) Applicant: STATE GRID ZHEJIANG ELECTRIC POWER CO., LTD. TAIZHOU POWER SUPPLY COMPANY, Taizhou (CN)

(72) Inventors: Jian Yang, Taizhou (CN); Yiping Shen, Taizhou (CN); Xinjian Chen, Taizhou (CN); Dongbo Zhang, Taizhou (CN); Jie Yu, Taizhou (CN); Yilun Zhu, Taizhou (CN); Guode Ying, Taizhou (CN); Bingren Wang, Taizhou (CN); Minyan Xia, Taizhou (CN); Huiying Gao, Taizhou (CN); Chenghuai Hong, Taizhou (CN); Yizhi Zhu, Taizhou (CN); Hongqing Zhou, Taizhou (CN); Qiulin Chen, Taizhou (CN); Chunyan Ding, Taizhou (CN); Chong Su, Taizhou (CN)

(21) Appl. No.: 17/109,176

(22) Filed: Dec. 2, 2020

Related U.S. Application Data
(63) Continuation-in-part of application No. PCT/CN2020/120258, filed on Oct. 11, 2020.

(30) Foreign Application Priority Data
Oct. 15, 2019 (CN) 201910977349.3

(51) Int. Cl. G01R 21/133; G06N 5/04; G06N 20/00

(52) U.S. Cl. CPC G01R 21/133; G06N 20/00; G06N 5/04

(57) ABSTRACT

The present invention relates to a method for identifying parameters of a 10 kV static load model based on similar daily load curves. In the present invention, an optimization model for identifying full-period parameters of the static load model is proposed based on a large number of daily load curves with response characteristic, a structure and constraints of the static load model, and two theoretical basic assumptions about loads. Full-period (including 96 moments) static voltage model parameters of 10 kV loads are given through optimization solution. A rule that active power and reactive power of the loads at each moment change with voltage is obtained. In addition, a change rule of load constituents is obtained. The method delivers good applicability, satisfies actual demands, and is suitable for large-scale static model analyses for 10 kV loads.

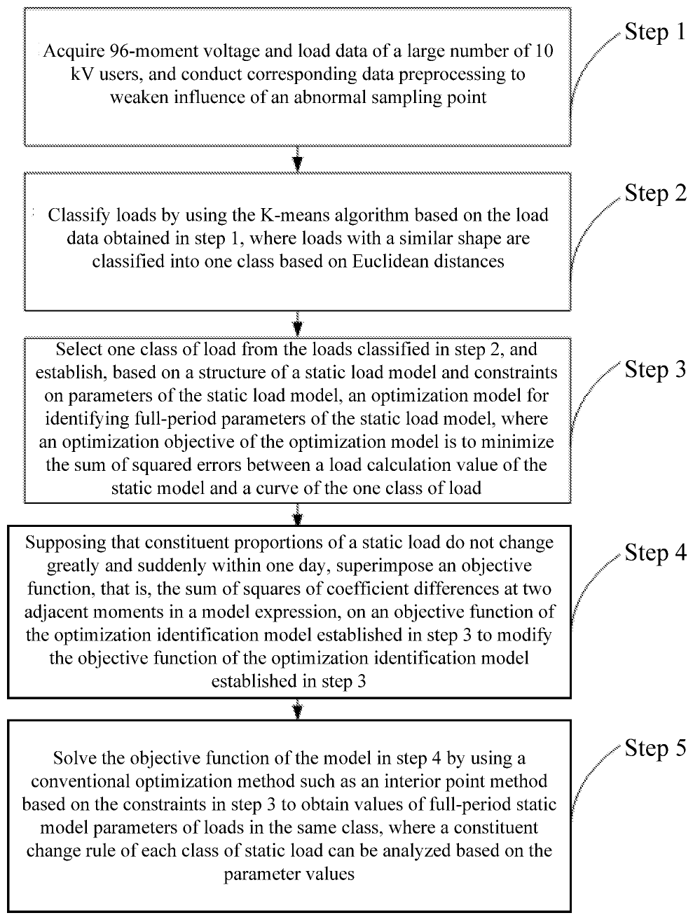

### CROSS REFERENCE TO RELATED APPLICATIONS

The present application is a Continuation-In-Part application of PCT Application No. PCT/CN2020/120258 filed on Oct. 11, 2020, which claims the benefit of Chinese Patent Application No. 201910977349.3 filed on Oct. 15, 2019. All the above are hereby incorporated by reference in their entirety.

### TECHNICAL FIELD

The present invention relates to the field of power system technologies, and in particular, to a method for identifying parameters of a 10 kV static load model based on similar daily load curves.

### BACKGROUND

A static load model is structurally classified into a power function model, a polynomial model, and a model in which the power function model is mixed with the polynomial model. Because frequency usually changes with an extremely small amplitude, the effect of frequency changes on load characteristics can be ignored. In addition, the polynomial load model has clearer physical meaning. To be specific, loads are obtained by superimposing constant impedance loads, constant current loads, constant power loads, etc. Therefore, the polynomial model is usually adopted for static loads in power system simulation analyses. The model is as follows:

$$\{ \begin{matrix}P = {P}_{0} [ {{p}_{z} ( \frac{V}{{V}_{0}} )}^{2} + {p}_{i} ( \frac{V}{{V}_{0}} ) + {p}_{p} ] , {p}_{z} + {p}_{i} + {p}_{p} = 1 \\ Q = {Q}_{0} [ {{q}_{z} ( \frac{V}{{V}_{0}} )}^{2} + {q}_{i} ( \frac{V}{{V}_{0}} ) + {q}_{p} ] , {q}_{z} + {q}_{i} + {q}_{p} = 1\end{matrix} .$$

In the model, p_{z} denotes a constant-impedance active power percentage, pᵢ denotes a constant-current active power percentage, pₚ denotes a constant-power active power percentage, q_{z} denotes a constant-impedance reactive power percentage, qᵢ denotes a constant-current reactive power percentage, and qₚ denotes a constant-power reactive power percentage. For a kth load curve, P₀ denotes an initial value of active power, and Q₀ denotes an initial value of reactive power.

When the model is used to describe daily load characteristics, the initial power value and ZIP coefficients in the model at each moment dynamically change. When ZIP model parameters are identified based on active power, reactive power, and voltage curves, the number of parameters to be solved in the model is greater than the number of equations. Therefore, accurate ZIP coefficients cannot be directly solved.

### SUMMARY

In view of this, an objective of the present invention is to establish an optimization model for identifying parameters of a static load model based on a structure of a static load model and a similar 10 kV daily load curve, and perform optimization solution by using an interior point method to obtain full-period (including 96 sampling moments) parameters of the static load model in one day, and obtain a change rule of load constituents to analyze the load constituents. The method delivers good applicability, satisfies actual demands, and is suitable for large-scale static modeling analyses for 10 kV loads.

The present invention adopts a method for identifying parameters of a 10 kV static load model based on similar daily load curves, including:

step 1: acquiring 96-moment voltage and load data of a large number of 10 kV users, and conducting corresponding data preprocessing to weaken influence of an abnormal sampling point;

step 2: classifying loads by using the K-means algorithm based on the load data obtained in step 1, wherein loads with a similar shape are classified into one class based on Euclidean distances;

step 3: selecting one class of load from the loads classified in step 2, and establishing, based on a structure of a static load model and constraints on parameters of the static load model, an optimization model for identifying full-period parameters of the static load model, wherein an optimization objective of the optimization model is to minimize the sum of squared errors between a load calculation value of the static model and a curve of the one class of load;

step 4: supposing that constituent proportions of a static load do not change greatly and suddenly within one day, superimposing an objective function, that is, a sum of squares of coefficient differences at two adjacent moments in a model expression, on an objective function of the optimization identification model established in step 3 to modify the objective function of the optimization identification model established in step 3; and

step 5: solving the objective function of the model in step 4 by using a conventional optimization method such as an interior point method based on the constraints in step 3 to obtain values of full-period static model parameters of loads in a same class, wherein a constituent change rule of each class of static load can be analyzed based on the parameter values.

Optionally, step 1 specifically includes:

performing the following smoothing processing on voltage V and loads P and Q of each 10 kV user:

when moment t=1 or 96, no processing is performed;

when moment t=2, the following processing is performed:

$${V}_{2}^{′} = \frac{{V}_{1} + {V}_{2} + {V}_{3}}{3} , {P}_{2}^{′} = \frac{{P}_{1} + {P}_{2} + {P}_{3}}{3} , {Q}_{2}^{′} = \frac{{Q}_{1} + {Q}_{2} + {Q}_{3}}{3} ;$$

when moment t=95, the following processing is performed:

$${V}_{95}^{′} = \frac{{V}_{94} + {V}_{95} + {V}_{96}}{3} , {V}_{95}^{′} = \frac{{P}_{94} + {P}_{95} + {P}_{96}}{3} , {Q}_{95}^{′} = \frac{{Q}_{94} + {Q}_{95} + {Q}_{96}}{3} ;$$

and

when 3≤t≤94, the following processing is performed:

$${V}_{t}^{′} = \frac{{V}_{t - 2} + {V}_{t - 1} + {V}_{t} + {V}_{t + 1} + {V}_{t + 2}}{5} , \\ {P}_{t}^{′} = \frac{{P}_{t - 2} + {P}_{t - 1} + {P}_{t} + {P}_{t + 1} + {P}_{t + 2}}{5} , \\ {Q}_{t}^{′} = \frac{{Q}_{t - 2} + {Q}_{t - 1} + {Q}_{t} + {Q}_{t + 1} + {Q}_{t + 2}}{5} ,$$

wherein

Vₜ denotes a voltage at moment t, V′ₜ denotes a processed voltage at moment t, Pₜ denotes a class-I load at moment t, P′ₜ denotes a processed class-I load at moment t, Qₜ denotes a class-II load at moment t, and Q′ₜ denotes a processed class-II load at moment t.

Optionally, step 2 specifically includes:

(1) randomly selecting h data points as initial cluster centers;

(2) calculating Euclidean distances from N data points to the h cluster centers one by one, and classifying the data points into classes that include cluster centers with minimum distances to the data points;

(3) after classifying the N data points, separately calculating means of data points in h classes, and using the means as new cluster centers of the h classes; and

(4) repeating steps (2) and (3) until cluster centers of the h classes no longer change; and

using two evaluation indexes to determine an optimal number of clusters and an optimal clustering result that takes into account randomness of the initial cluster centers.

Optionally, the using two evaluation indexes to determine an optimal number of clusters and an optimal clustering result that takes into account randomness of the initial cluster centers includes:

(1) using Davies-Bouldin index I_{DB} to determine the optimal number of clusters, wherein

I_{DB} is calculated as follows:

$${I}_{D B} = \frac{1}{h} {\sum }_{i \neq j}^{h} max ( \frac{\overline{{d}_{i}} + \overline{{d}_{j}}}{{‖ {c}_{i} - {c}_{j} ‖}_{2}} ) ,$$

wherein

h denotes the number of clusters; cᵢ and cⱼ denote cluster centers of an i th class and a j th class respectively; and d̅ᵢ̅ and d̅ⱼ̅ denote average distances from data points in the i th class and the j th class to cluster centers cᵢ and cⱼ of corresponding classes respectively;

(2) using the sum of squared errors (SSE) index I_{SSE} to evaluate clustering results corresponding to different initial cluster centers; to be specific, setting the number of times of clustering first, and then calculating a corresponding I_{SSE} value based on a result of each time of clustering, and finally selecting a clustering result corresponding to the minimum I_{SSE}, wherein I_{SSE} is calculated as follows:

$${I}_{S S E} = {\sum }_{i = 1}^{h} {\sum }_{k = 1}^{{n}_{i}} {‖ {c}_{i k} - {c}_{i} ‖}_{2} ,$$

wherein

n₁ denotes the number of data points in the i th class, cᵢₖ denotes a kth data point in the i th class, and cᵢ denotes the cluster center of the i th class; and

(3) obtaining the optimal clustering result of loads through a plurality of times of clustering based on Davies-Bouldin index I_{DB} and SSE index I_{SSE}.

Optionally, step 3 specifically includes:

selecting class-I daily load curves based on the clustering result obtained in step 2, selecting N curves with shapes closest to each other from the class-I daily load curves, and optimizing and identifying static load models corresponding to the N load curves;

a static load model of a kth curve at moment t is expressed as follows:

$$\{ \begin{matrix}{P}_{kt} = {P}_{0 kt} [ {{p}_{zkt} ( \frac{{V}_{kt}}{{V}_{0 k}} )}^{2} + {p}_{ikt} ( \frac{{V}_{kt}}{{V}_{0 k}} ) + {p}_{pkt} ] , {p}_{zkt} + {p}_{ikt} + {p}_{pkt} = 1 \\ {Q}_{kt} = {Q}_{0 kt} [ {{q}_{zkt} ( \frac{{V}_{kt}}{{V}_{0 k}} )}^{2} + {q}_{ikt} ( \frac{{V}_{kt}}{{V}_{0 k}} ) + {q}_{pkt} ] , {q}_{zkt} + {q}_{ikt} + {q}_{pkt} = 1\end{matrix} ,$$

wherein

k=1, 2, . . . , N−1, N; and t=1, 2, . . . , 95, 96;

the model includes a large number of parameters p_{zkt}, pᵢₖₜ, pₚₖₜ, q_{zkt}, qᵢₖₜ, qₚₖₜ, P₀ₖₜ, Q₀ₖₜ to be identified, wherein for the kth load curve, p_{zkt} denotes a constant-impedance active power percentage, pᵢₖₜ denotes a constant-current active power percentage, pₚₖₜ denotes a constant-power active power percentage, q_{zkt} denotes a constant-impedance reactive power percentage, qᵢₖₜ denotes a constant-current reactive power percentage, qₚₖₜ denotes a constant-power reactive power percentage, P₀ₖₜ denotes an initial value of active power, Q₀ₖₜ denotes an initial value of reactive power, V₀ₖ denotes a voltage at moment 0, that is, an initial voltage, and Vₖₜ denotes a voltage at moment t; the following assumption is proposed considering that constituents of loads in the same class are theoretically similar:

basic assumption 1: for loads in the same class that are determined based on differences in load curve shapes, constituent proportions of the loads at the same moment differ slightly; to be specific, parameters such as p_{zkt}, pᵢₖₜ, pₚₖₜ, q_{zkt}, qᵢₖₜ, and qₚₖₜ differ slightly between different loads in the same class, but P₀ₖₜ and Q₀ₖₜ differ obviously;

based on assumption 1, the loads in the same class can be identified together; specifically, constituent proportion differences between the loads in the same class at the same moment is ignored, and in this case, the number of parameters to be identified for the loads in the class is reduced greatly, and the parameters are p_{zt}, pᵢₜ, pₚₜ, q_{zt}, qᵢₜ, qₚₜ, P₀ₖₜ, and Q₀ₖₜ; for all the N loads, p_{zt} denotes a constant-impedance active power percentage, pᵢₜ denotes a constant-current active power percentage, pₚₜ denotes a constant-power active power percentage, q_{zt} denotes a constant-impedance reactive power percentage, qᵢₜ denotes a constant-current reactive power percentage, and qₚₜ denotes a constant-power reactive power percentage; for the kth load curve, P₀ₖₜ denotes the initial value of active power, and Q₀ₖₜ denotes the initial value of reactive power;

optimal values of the parameters to be identified should minimize the sum of squared errors between load model calculation values of the loads in the same class at each moment and corresponding measurement values; therefore, this is the basis of the optimization model for identifying parameters;

an optimization model for identifying parameters of a static active power model is as follows:

the objective function is

$$min f = {\sum }_{k = 1}^{N} {\sum }_{t = 1}^{96} {( {P}_{kt} - {P}_{kt}^{′} )}^{2} ,$$

wherein

Pₖₜ denotes a theoretical active load calculated by using a static load model expression at moment t, and Pₖₜ′ denotes an actual active load at moment t; and

the constraints are

$$\{ \begin{matrix}{p}_{zkt} + {p}_{ikt} + {p}_{pkt} = 1 \\ 0 \leq {p}_{zkt} \leq 1 \\ 0 \leq {p}_{ikt} \leq 1 \\ 0 \leq {p}_{zkt} + {p}_{ikt} \leq 1 \\ k = 1 , 2 , … , N - 1 , N \\ t = 1 , 2 , … , 95 , 96\end{matrix} ;$$

and

an optimization model for identifying parameters of a static reactive power model is as follows:

the objective function is

$$min f = {\sum }_{k = 1}^{N} {\sum }_{t = 1}^{96} {( {Q}_{kt} - {Q}_{kt}^{′} )}^{2} ,$$

wherein

Qₖₜ denotes a theoretical reactive load calculated by using the static load model expression for the kth load at moment t, and Qₖₜ′ denotes an actual reactive load of the kth load at moment t; and

the constraints are

$$\{ \begin{matrix}{q}_{zkt} + {q}_{ikt} + {q}_{pkt} = 1 \\ 0 \leq {q}_{zkt} \leq 1 \\ 0 \leq {q}_{ikt} \leq 1 \\ 0 \leq {q}_{zkt} + {q}_{ikt} \leq 1 \\ k = 1 , 2 , … , N - 1 , N \\ t = 1 , 2 , … , 95 , 96\end{matrix} .$$

Optionally, step 4 specifically includes:

modifying the objective function of the optimization model in step 3, considering that constituent proportions of static loads do not change greatly and suddenly within one day;

in theory, the following conditions exist in terms of loads:

basic assumption 2: the constituent proportions of static loads do not change greatly and suddenly within one day;

based on assumption 2, the sum of squares of differences between static load constituent proportions of the loads in the same class at two adjacent moments is superimposed on the original objective function to modify the objective function;

the objective functions of the optimization models for identifying parameters of a static reactive power model and a static active power model are respectively modified to

$$min f = {\sum }_{k = 1}^{N} {\sum }_{t = 1}^{96} {( {P}_{kt} - {P}_{kt}^{′} )}^{2} + {\sum }_{t = 2}^{96} [ {( {p}_{zkt} - {p}_{zk , t - 1} )}^{2} + {( {P}_{ikt} - {P}_{ik , t - 1} )}^{2} ] and$$

$$min f = {\sum }_{k = 1}^{N} {\sum }_{t = 1}^{96} {( {Q}_{kt} - {Q}_{kt}^{′} )}^{2} + {\sum }_{t = 2}^{96} [ {( {q}_{zkt} - {q}_{zk , t - 1} )}^{2} + {( {q}_{ikt} - {q}_{ik , t - 1} )}^{2} ] ,$$

wherein
p_{zk,t-1} denotes a constant-impedance active power percentage of the kth load at moment t−1, P_{ik,t-1} denotes a constant-current active power percentage of the kth load at moment t−1, q_{zk,t-1} denotes a constant-impedance reactive power percentage of the kth load at moment t−1, and q_{ik,t-1} denotes a constant-current reactive power percentage of the kth load at moment t−1.

Optionally, step 5 specifically includes:

solving the objective functions of the optimization models for identifying parameters of a static reactive power model and a static active power model in step 4 by using an optimization method such as the interior point method based on the constraints of the static active power and reactive power models in step 3 to obtain full-period parameter values of the static active power and reactive power load models.

The beneficial effects of the present invention are as follows:

Full-period (including 96 moments) static voltage model parameters of 10 kV loads are given through clustering and optimization solution, and the rule that active power and reactive power of loads at each moment change with voltage is analyzed.

### BRIEF DESCRIPTION OF DRAWINGS

The sole FIGURE is a schematic flowchart of a method for identifying parameters of a 10 kV static load model based on similar daily load curves according to an embodiment of the present invention.

### DETAILED DESCRIPTION

The present invention is further described with reference to the accompanying drawings and embodiments.

In practice, a power grid acquires all information about electricity consumption of general-purpose and special-purpose transformer customers, and covers a load control and management system for a distribution network. In addition, the power grid is equipped with intelligent measurement terminals, and connected to power grid management information platforms such as a marketing and distribution system, a supervisory control and data acquisition (SCADA) system, and a Hisun information system. This provides a large amount of load data for implementation of the present invention.

An embodiment provides a method for identifying parameters of a 10 kV static load model based on similar daily load curves. As shown in the FIGURE, the method includes the following steps:

Step 1: Acquire 96-moment voltage and load data of a large number of 10 kV users, and conduct corresponding data preprocessing to weaken influence of an abnormal sampling point.

Step 2: Classify loads by using the K-means algorithm based on the load data obtained in step 1, where loads with a similar shape are classified into one class based on Euclidean distances.

Step 3: Select one class of load from the loads classified in step 2, and establish, based on a structure of a static load model and constraints on parameters of the static load model, an optimization model for identifying full-period parameters of the static load model, where an optimization objective of the optimization model is to minimize the sum of squared errors between a load calculation value of the static model and a curve of the one class of load.

Step 4: Supposing that constituent proportions of a static load do not change greatly and suddenly within one day, superimpose an objective function, that is, the sum of squares of coefficient differences at two adjacent moments in a model expression, on an objective function of the optimization model established in step 3 to modify the objective function in step 3.

Step 5: Solve the objective function of the model in step 4 by using a conventional optimization method such as an interior point method based on the constraints in step 3 to obtain values of full-period static model parameters of loads in the same class, where a constituent change rule of each class of static load can be analyzed based on the parameter values.

Further, step 1 may be specifically performing the following smoothing processing on voltage V and loads P and Q of each 10 kV user:

When moment t=1 or 96, no processing is performed.

When moment t=2, the following processing is performed:

$${V}_{2}^{′} = \frac{{V}_{1} + {V}_{2} + {V}_{3}}{3} , {P}_{2}^{′} = \frac{{P}_{1} + {P}_{2} + {P}_{3}}{3} , {Q}_{2}^{′} = \frac{{Q}_{1} + {Q}_{2} + {Q}_{3}}{3} .$$

When moment t=95, the following processing is performed:

$${V}_{95}^{′} = \frac{{V}_{94} + {V}_{95} + {V}_{96}}{3} , {P}_{95}^{′} = \frac{{P}_{94} + {P}_{95} + {P}_{96}}{3} , {Q}_{95}^{′} = \frac{{Q}_{94} + {Q}_{95} + {Q}_{96}}{3} .$$

When 3≤t≤94, the following processing is performed:

$${V}_{t}^{′} = \frac{{V}_{t - 2} + {V}_{t - 1} + {V}_{t} + {V}_{t + 1} + {V}_{t + 2}}{5} , \\ {P}_{t}^{′} = \frac{{P}_{t - 2} + {P}_{t - 1} + {P}_{t} + {P}_{t + 1} + {P}_{t + 2}}{5} , \\ {Q}_{t}^{′} = \frac{{Q}_{t - 2} + {Q}_{t - 1} + {Q}_{t} + {Q}_{t + 1} + {Q}_{t + 2}}{5} ,$$

where

Vₜ denotes a voltage at moment t, V′ₜ denotes a processed voltage at moment t, Pₜ denotes a class-I load at moment t, P′ₜ denotes a processed class-I load at moment t, Qₜ denotes a class-II load at moment t, and Q′ₜ denotes a processed class-II load at moment t.

Further, step 2 may be specifically classifying the loads by using the K-means algorithm. The K-means algorithm is a typical algorithm in the field of clustering analysis. Its basic idea is to classify N data points into h classes to minimize the sum of distances from a cluster center of each class to all data points in the class.

Clustering based on the K-means algorithm may be implemented as follows:

(1) Randomly select h data points as initial cluster centers.

(2) Calculate Euclidean distances from N data points to the h cluster centers one by one, and classify the data points into classes that include cluster centers with minimum distances to the data points.

(3) After classifying the N data points, separately calculate means of data points in h classes, and use the means as new cluster centers of the h classes.

(4) Repeat steps (2) and (3) until cluster centers of the h classes no longer change.

Two evaluation indexes may be used to determine an optimal number of clusters and an optimal clustering result that takes into account randomness of the initial cluster centers.

First, Davies-Bouldin index I_{DB} may be used to determine the optimal number of clusters.

I_{DB} may be calculated as follows:

$${I}_{D B} = \frac{1}{h} {\sum }_{i \neq j}^{h} max ( \frac{\overline{{d}_{i}} + \overline{{d}_{j}}}{{‖ {c}_{i} - {c}_{j} ‖}_{2}} ) .$$

In the formula, h denotes the number of clusters; cᵢ and cⱼ denote cluster centers of an i th class and a j th class respectively; and d̅ᵢ̅ the d̅ⱼ̅ denote average distances from data points in the i th class and the j th class to cluster centers cᵢ and cⱼ of corresponding classes respectively.

Then sum of squared errors (SSE) index I_{SSE} may be used to evaluate clustering results corresponding to different initial cluster centers. First, the number of times of clustering was set. Then a corresponding I_{SSE} value was calculated based on a result of each time of clustering. Finally, a clustering result corresponding to the minimum I_{SSE} was selected. I_{SSE} may be calculated as follows:

$${I}_{S S E} = {\sum }_{i = 1}^{h} {\sum }_{k = 1}^{{n}_{i}} {‖ {c}_{i k} - {c}_{i} ‖}_{2} .$$

In the formula, nᵢ denotes the number of data points in the i th class, cᵢₖ denotes a kth data point in the i th class, and cᵢ denotes the cluster center of the i th class.

The optimal clustering result of loads may be obtained through a plurality times of clustering based on the two indexes.

Further, step 3 may be specifically selecting class-I daily load curves based on the clustering result obtained in step 2, selecting N curves with shapes closest to each other from the class-I daily load curves, and optimizing and identifying static load models corresponding to the N load curves.

A static load model of a kth curve at moment t may be expressed as follows:

$$\{ \begin{matrix}{P}_{kt} = {P}_{0 kt} [ {{p}_{zkt} ( \frac{{V}_{kt}}{{V}_{0 k}} )}^{2} + {p}_{ikt} ( \frac{{V}_{kt}}{{V}_{0 k}} ) + {p}_{pkt} ] , {p}_{zkt} + {p}_{ikt} + {p}_{pkt} = 1 \\ {Q}_{kt} = {Q}_{0 kt} [ {{q}_{zkt} ( \frac{{V}_{kt}}{{V}_{0 k}} )}^{2} + {q}_{ikt} ( \frac{{V}_{kt}}{{V}_{0 k}} ) + {q}_{pkt} ] , {q}_{zkt} + {q}_{ikt} + {q}_{pkt} = 1\end{matrix} ,$$

where

k=1, 2, . . . , N−1, N; and t=1, 2, . . . , 95, 96.

The model includes a large number of parameters p_{zkt}, pᵢₖₜ, pₚₖₜ, q_{zkt}, qᵢₖₜ, qₚₖₜ, P₀ₖₜ, Q₀ₖₜ to be identified. For the kth load curve, p_{zkt} denotes a constant-impedance active power percentage, pᵢₖₜ denotes a constant-current active power percentage, pₚₖₜ denotes a constant-power active power percentage, q_{zkt} denotes a constant-impedance reactive power percentage, qᵢₖₜ denotes a constant-current reactive power percentage, qₚₖₜ denotes a constant-power reactive power percentage, P₀ₖₜ denotes an initial value of active power, Q₀ₖₜ denotes an initial value of reactive power, denotes a voltage at moment 0, that is, an initial voltage, and Vₖₜ denotes a voltage at moment t. The following assumption is proposed considering that constituents of loads in the same class are theoretically similar:

Basic assumption 1: for loads in the same class that are determined based on differences in load curve shapes, constituent proportions of the loads at the same moment differ slightly. To be specific, parameters such as p_{zkt}, pᵢₖₜ, pₚₖₜ, q_{zkt}, qᵢₖₜ, and qₚₖₜ differ slightly between different loads in the same class, but P₀ₖₜ and Q₀ₖₜ differ obviously.

Based on assumption 1, the loads in the same class may be identified together. Specifically, constituent proportion differences between the loads in the same class at the same moment may be ignored. In this case, the number of parameters to be identified for the loads in the class may be reduced greatly, and the parameters may be p_{zt}, pᵢₜ, pₚₜ, q_{zt}, qᵢₜ, qₚₜ, P₀ₖₜ, and Q₀ₖₜ. For all the N loads, p_{zt} denotes a constant-impedance active power percentage, pᵢₜ denotes a constant-current active power percentage, pₚₜ denotes a constant-power active power percentage, q_{zt} denotes a constant-impedance reactive power percentage, qᵢₜ denotes a constant-current reactive power percentage, and qₚₜ denotes a constant-power reactive power percentage. For the kth load curve, P₀ₖₜ denotes the initial value of active power, and Q₀ₖₜ denotes the initial value of reactive power.

Optimal values of the parameters to be identified should minimize the sum of squared errors between load model calculation values of the loads in the same class at each moment and corresponding measurement values. Therefore, this is the basis of the optimization model for identifying parameters. Parameters of active power and reactive power models may be identified separately by using similar methods.

An optimization model for identifying parameters of a static active power model may be as follows:

the objective function is

$$min f = {\sum }_{k = 1}^{N} {\sum }_{t = 1}^{96} {( {P}_{k t} - {P}_{k t}^{′} )}^{2} ,$$

where

Pₖₜ denotes a theoretical active load calculated by using a static load model expression at moment t, and Pₖₜ′ denotes an actual active load at moment t; and

the constraints are

$$\{ \begin{matrix}{p}_{zkt} + {p}_{ikt} + {p}_{pkt} = 1 \\ 0 \leq {p}_{zkt} \leq 1 \\ 0 \leq {p}_{ikt} \leq 1 \\ 0 \leq {p}_{zkt} + {p}_{ikt} \leq 1 \\ k = 1 , 2 , … , N - 1 , N \\ t = 1 , 2 , … , 95 , 96\end{matrix} ,$$

An optimization model for identifying parameters of a static reactive power model may be as follows:

the objective function is

$$min f = {\sum }_{k = 1}^{N} {\sum }_{t = 1}^{96} {( {Q}_{k t} - {Q}_{kt}^{′} )}^{2} ,$$

where

Qₖₜ denotes a theoretical reactive load calculated by using the static load model expression for the kth load at moment t, and Qₖₜ′ denotes an actual reactive load of the kth load at moment t; and

the constraints are

$$\{ \begin{matrix}{p}_{zkt} + {p}_{ikt} + {p}_{pkt} = 1 \\ 0 \leq {p}_{zkt} \leq 1 \\ 0 \leq {p}_{ikt} \leq 1 \\ 0 \leq {p}_{zkt} + {p}_{ikt} \leq 1 \\ k = 1 , 2 , … , N - 1 , N \\ t = 1 , 2 , … , 95 , 96\end{matrix} .$$

Further, step 4 may be specifically modifying the objective function of the optimization model in step 3, supposing that constituent proportions of static loads do not change greatly and suddenly within one day.

In theory, the following conditions may exist in terms of loads:

Basic assumption 2: the constituent proportions of static loads do not change greatly and suddenly within one day.

Based on assumption 2, the sum of squares of differences between static load constituent proportions of the loads in the same class at two adjacent moments may be superimposed on the original objective function to modify the objective function.

The objective functions of the optimization models for identifying parameters of a static reactive power model and a static active power model may be respectively modified to

$$min f = {\sum }_{k = 1}^{N} {\sum }_{t = 1}^{96} {( {Q}_{k t} - {Q}_{kt}^{′} )}^{2} + {\sum }_{t = 2}^{96} [ {( {q}_{z k t} - {q}_{zk , t - 1} )}^{2} + {( {q}_{i k t} - {q}_{i k , t - 1} )}^{2} ] and$$

$$min f = {\sum }_{k = 1}^{N} {\sum }_{t = 1}^{96} {( {Q}_{k t} - {Q}_{kt}^{′} )}^{2} + {\sum }_{t = 2}^{96} [ {( {q}_{z k t} - {q}_{zk , t - 1} )}^{2} + {( {q}_{i k t} - {q}_{i k , t - 1} )}^{2} ] ,$$

where

p_{zk,t-1} denotes a constant-impedance active power percentage of the kth load at moment t−1, p_{ik,t-1} denotes a constant-current active power percentage of the kth load at moment t−1, q_{zk,t-1} denotes a constant-impedance reactive power percentage of the kth load at moment t−1, and q_{ik,t-1} denotes a constant-current reactive power percentage of the kth load at moment t−1.

Further, step 5 may be specifically solving the objective functions of the optimization models for identifying parameters of a static reactive power model and a static active power model in step 4 by using an optimization method such as the interior point method based on the constraints of the static active power and reactive power models in step 3 to obtain full-period parameter values of the static active power and reactive power load models.

In the present invention, full-period (including 96 moments) static voltage model parameters of 10 kV loads are given through clustering and optimization solution based on a large number of daily load curves with response characteristic and the two theoretical basic assumptions. In addition, a rule that active power and reactive power of the loads at each moment change with voltage is analyzed. The full-period parameters of the 10 kV static load model are optimized and identified by performing the foregoing steps. As a result, the foregoing steps provide a method for analyzing a full-period change rule of static load model constituents.

The aforementioned are only preferred embodiments of the present invention, and all equivalent changes and modifications made in accordance with the claims of the present invention shall fall within the scope of the present invention.

1. A method for identifying parameters of a 10 kV static load model based on similar daily load curves, comprising:
step 1: acquiring 96-moment voltage and load data of a large number of 10 kV users, and conducting corresponding data preprocessing to weaken influence of an abnormal sampling point;
step 2: classifying loads by using the K-means algorithm based on the load data obtained in step 1, wherein loads with a similar shape are classified into one class based on Euclidean distances;
step 3: selecting one class of load from the loads classified in step 2 successively, and establishing, based on a structure of a static load model and constraints on parameters of the static load model, an optimization model for identifying full-period parameters of the static load model, wherein an optimization objective of the optimization model is to minimize the sum of squared errors between a load calculation value of the static model and a curve of the one class of load;
step 4: supposing that constituent proportions of a static load do not change greatly and suddenly within one day, superimposing an objective function, that is, a sum of squares of coefficient differences at two adjacent moments in a model expression, on an objective function of the optimization identification model established in step 3 to modify the objective function of the optimization identification model established in step 3; and
step 5: solving the objective function of the model in step 4 by using a conventional optimization method such as an interior point method based on the constraints in step 3 to obtain values of full-period static model parameters of loads in a same class, wherein a constituent change rule of each class of static load can be analyzed based on the parameter values.

2. The method for identifying parameters of a 10 kV static load model based on similar daily load curves according to claim 1, wherein step 1 specifically comprises:
performing the following smoothing processing on voltage V and loads P and Q of each 10 kV user:
when moment t=1 or 96, no processing is performed;
when moment t=2, the following processing is performed:
$${V}_{2}^{′} = \frac{{V}_{1} + {V}_{2} + {V}_{3}}{3} , {P}_{2}^{′} = \frac{{P}_{1} + {P}_{2} + {P}_{3}}{3} , {Q}_{2}^{′} = \frac{{Q}_{1} + {Q}_{2} + {Q}_{3}}{3} ;$$
when moment t=95, the following processing is performed:
$${V}_{95}^{′} = \frac{{V}_{94} + {V}_{95} + {V}_{96}}{3} , {P}_{95}^{′} = \frac{{P}_{94} + {P}_{95} + {P}_{96}}{3} , {Q}_{95}^{′} = \frac{{Q}_{94} + {Q}_{95} + {Q}_{96}}{3} ;$$
and
when 3≤t≤94, the following processing is performed:
$${V}_{t}^{′} = \frac{{V}_{t - 2} + {V}_{t - 1} + {V}_{t} + {V}_{t + 1} + {V}_{t + 2}}{5} , \\ {P}_{t}^{′} = \frac{{P}_{t - 2} + {P}_{t - 1} + {P}_{t} + {P}_{t + 1} + {P}_{t + 2}}{5} , \\ {Q}_{t}^{′} = \frac{{Q}_{t - 2} + {Q}_{t - 1} + {Q}_{t} + {Q}_{t + 1} + {Q}_{t + 2}}{5} ,$$
wherein
Vₜ denotes a voltage at moment t, V′ₜ denotes a processed voltage at moment t, Pₜ denotes a class-I load at moment t, P′ₜ denotes a processed class-I load at moment t, Qₜ denotes a class-II load at moment t, and Q′ₜ denotes a processed class-II load at moment t.

3. The method for identifying parameters of a 10 kV static load model based on similar daily load curves according to claim 1, wherein step 2 specifically comprises:
(1) randomly selecting h data points as initial cluster centers;
(2) calculating Euclidean distances from N data points to the h cluster centers one by one, and classifying the data points into classes that comprise cluster centers with minimum distances to the data points;
(3) after classifying the N data points, separately calculating means of data points in h classes, and using the means as new cluster centers of the h classes; and
(4) repeating steps (2) and (3) until cluster centers of the h classes no longer change; and
using two evaluation indexes to determine an optimal number of clusters and an optimal clustering result that takes into account randomness of the initial cluster centers.

4. The method for identifying parameters of a 10 kV static load model based on similar daily load curves according to claim 3, wherein the using two evaluation indexes to determine an optimal number of clusters and an optimal clustering result that takes into account randomness of the initial cluster centers comprises:
(1) using Davies-Bouldin index I_{DB} to determine the optimal number of clusters, wherein I_{DB} is calculated as follows:
$${I}_{D B} = \frac{1}{h} {\sum }_{i \neq j}^{h} max ( \frac{\overline{{d}_{i}} + \overline{{d}_{j}}}{{‖ {c}_{i} - {c}_{j} ‖}_{2}} ) ,$$
wherein
h denotes the number of clusters; cᵢ and cⱼ denote cluster centers of an i th class and a j th class respectively; and d̅ᵢ̅ and d̅ⱼ̅ denote average distances from data points in the i th class and the j th class to cluster centers cᵢ and cⱼ of corresponding classes respectively;
(2) using the sum of squared errors (SSE) index I_{SSE} to evaluate clustering results corresponding to different initial cluster centers; to be specific, setting the number of times of clustering first, and then calculating a corresponding I_{SSE} value based on a result of each time of clustering, and finally selecting a clustering result corresponding to the minimum I_{SSE}, wherein I_{SSE} is calculated as follows:
$${I}_{S S E} = {{\sum }_{i = 1}}^{h} {{\sum }_{k = 1}}^{{n}_{i}} {‖ {c}_{ik} - {c}_{i} ‖}_{2} ,$$
wherein
nᵢ denotes the number of data points in the i th class, cᵢₖ denotes a k th data point in the i th class, and cᵢ denotes the cluster center of the i th class; and
(3) obtaining the optimal clustering result of loads through a plurality of times of clustering based on Davies-Bouldin index I_{DB} and SSE index I_{SSE}.

5. The method for identifying parameters of a 10 kV static load model based on similar daily load curves according to claim 1, wherein step 3 specifically comprises:
selecting class-I daily load curves based on the clustering result obtained in step 2, selecting N curves with shapes closest to each other from the class-I daily load curves, and optimizing and identifying static load models corresponding to the N load curves;
a static load model of a kth curve at moment t is expressed as follows:
$$\{ \begin{matrix}{P}_{kt} = {P}_{0 kt} [ {{p}_{zkt} ( \frac{{V}_{kt}}{{V}_{0 k}} )}^{2} + {p}_{ikt} ( \frac{{V}_{kt}}{{V}_{0 k}} ) + {p}_{pkt} ] , {p}_{zkt} + {p}_{ikt} + {p}_{zkt} = 1 \\ {Q}_{kt} = {Q}_{0 kt} [ {{q}_{zkt} ( \frac{{V}_{kt}}{{V}_{0 k}} )}^{2} + {q}_{ikt} ( \frac{{V}_{kt}}{{V}_{0 k}} ) + {q}_{pkt} ] , {q}_{zkt} + {q}_{ikt} + {q}_{zkt} = 1\end{matrix} ,$$
wherein
k=1, 2, . . . , N−1, N; and t=1, 2, 95, 96;
the model comprises a large number of parameters p_{zkt}, pᵢₖₜ, pₚₖₜ, q_{zkt}, qᵢₖₜ, qₚₖₜ, P₀ₖₜ, Q₀ₖₜ to be identified, wherein for the kth load curve, p_{zkt} denotes a constant-impedance active power percentage, pᵢₖₜ denotes a constant-current active power percentage, pₚₖₜ denotes a constant-power active power percentage, q_{zkt} denotes a constant-impedance reactive power percentage, qᵢₖₜ denotes a constant-current reactive power percentage, qₚₖₜ denotes a constant-power reactive power percentage, P₀ₖₜ denotes an initial value of active power, Q₀ₖₜ denotes an initial value of reactive power, V₀ₖ denotes a voltage at moment 0, that is, an initial voltage, and Vₖₜ denotes a voltage at moment t; the following assumption is proposed considering that constituents of loads in the same class are theoretically similar:
basic assumption 1: for loads in the same class that are determined based on differences in load curve shapes, constituent proportions of the loads at the same moment differ slightly; to be specific, parameters such as p_{zkt}, pᵢₖₜ, pₚₖₜ, q_{zkt}, qᵢₖₜ, and qₚₖₜ differ slightly between different loads in the same class, but P₀ₖₜ and Q₀ₖₜ differ obviously;
based on assumption 1, the loads in the same class can be identified together; specifically, constituent proportion differences between the loads in the same class at the same moment is ignored, and in this case, the number of parameters to be identified for the loads in the class is reduced greatly, and the parameters are p_{zt}, pᵢₜ, pₚₜ, q_{zt}, qᵢₜ, qₚₜ, P₀ₖₜ, and Q₀ₖₜ; for all the N loads, p_{zt} denotes a constant-impedance active power percentage, pᵢₜ denotes a constant-current active power percentage, pₚₜ denotes a constant-power active power percentage, q_{zt} denotes a constant-impedance reactive power percentage, qᵢₜ denotes a constant-current reactive power percentage, and qₚₜ denotes a constant-power reactive power percentage; for the kth load curve, P₀ₖₜ denotes the initial value of active power, and Q₀ₖₜ denotes the initial value of reactive power;
optimal values of the parameters to be identified should minimize the sum of squared errors between load model calculation values of the loads in the same class at each moment and corresponding measurement values; therefore, this is the basis of the optimization model for identifying parameters;
an optimization model for identifying parameters of a static active power model is as follows:
the objective function is
$$min f = {\sum }_{k = 1}^{N} {\sum }_{t = 1}^{96} {( {P}_{k t} - {P}_{kt}^{′} )}^{2} ,$$
wherein
Pₖₜ denotes a theoretical active load calculated by using a static load model expression at moment t, and Pₖₜ′ denotes an actual active load at moment t; and
the constraints are
$$\{ \begin{matrix}{p}_{zkt} + {p}_{ikt} + {p}_{pkt} = 1 \\ 0 \leq {p}_{zkt} \leq 1 \\ 0 \leq {p}_{ikt} \leq 1 \\ 0 \leq {p}_{zkt} + {p}_{ikt} \leq 1 \\ k = 1 , 2 , … , N - 1 , N \\ i = 1 , 2 , … , 95 , 96\end{matrix} ;$$
and
an optimization model for identifying parameters of a static reactive power model is as follows:
the objective function is
$$min f = {\sum }_{k = 1}^{N} {\sum }_{t = 1}^{96} {( {P}_{k t} - {P}_{kt}^{′} )}^{2} ,$$
wherein
Qₖₜ denotes a theoretical reactive load calculated by using the static load model expression for the kth load at moment t, and Qₖₜ′ denotes an actual reactive load of the kth load at moment t; and
the constraints are
$$\{ \begin{matrix}{p}_{zkt} + {p}_{ikt} + {p}_{pkt} = 1 \\ 0 \leq {p}_{zkt} \leq 1 \\ 0 \leq {p}_{ikt} \leq 1 \\ 0 \leq {p}_{zkt} + {p}_{ikt} \leq 1 \\ k = 1 , 2 , … , N - 1 , N \\ i = 1 , 2 , … , 95 , 96\end{matrix} .$$

6. The method for identifying parameters of a 10 kV static load model based on similar daily load curves according to claim 5, wherein step 4 specifically comprises:
modifying the objective function of the optimization model in step 3, considering that constituent proportions of static loads do not change greatly and suddenly within one day;
in theory, the following conditions exist in terms of loads:
basic assumption 2: the constituent proportions of static loads do not change greatly and suddenly within one day;
based on assumption 2, the sum of squares of differences between static load constituent proportions of the loads in the same class at two adjacent moments is superimposed on the original objective function to modify the objective function;
the objective functions of the optimization models for identifying parameters of a static reactive power model and a static active power model are respectively modified to
$$min f = {\sum }_{k = 1}^{N} {\sum }_{t = 1}^{96} {( {Q}_{k t} - {Q}_{kt}^{′} )}^{2} + {\sum }_{t = 2}^{96} [ {( {q}_{z k t} - {q}_{zk , t - 1} )}^{2} + {( {q}_{i k t} - {q}_{i k , t - 1} )}^{2} ] and$$
$$min f = {\sum }_{k = 1}^{N} {\sum }_{t = 1}^{96} {( {Q}_{k t} - {Q}_{kt}^{′} )}^{2} + {\sum }_{t = 2}^{96} [ {( {q}_{z k t} - {q}_{zk , t - 1} )}^{2} + {( {q}_{i k t} - {q}_{i k , t - 1} )}^{2} ] ,$$
wherein
p_{zk,t-1} denotes a constant-impedance active power percentage of the kth load at moment t−1, p_{ik,t-1} denotes a constant-current active power percentage of the kth load at moment t−1, q_{zk,t-1} denotes a constant-impedance reactive power percentage of the kth load at moment t−1, and q_{ik,t-1} denotes a constant-current reactive power percentage of the kth load at moment t−1.

7. The method for identifying parameters of a 10 kV static load model based on similar daily load curves according to claim 6, wherein step 5 specifically comprises:
solving the objective functions of the optimization models for identifying parameters of a static reactive power model and a static active power model in step 4 by using an optimization method such as the interior point method based on the constraints of the static active power and reactive power models in step 3 to obtain full-period parameter values of the static active power and reactive power load models.
